(19) United States
(12) Patent Application Publication
(10) Pub. No.: US 2025/0127019 A1
(43) Pub. Date: Apr. 17, 2025

(54) DISPLAY DEVICE

(71) Applicant: LG Display Co., Ltd., Seoul (KR)

(72) Inventors: Insu HWANG, Seoul (KR); MinKee KO, Paju-si (KR)

(73) Assignee: LG Display Co., Ltd., Seoul (KR)

(21) Appl. No.: 18/917,880

(22) Filed: Oct. 16, 2024

(30) Foreign Application Priority Data
Oct. 17, 2023 (KR) 10-2023-0138606

(51) Int. Cl. H10K 59/80; H10K 59/131

(52) U.S. Cl. CPC H10K 59/873; H10K 59/131; H10K 59/874

(57) ABSTRACT

A display device can include a base substrate having a display area and a non-display area surrounding the display area, an encapsulation substrate disposed on the base substrate and covering the display area, a dam disposed between the base substrate and the encapsulation substrate in the non-display are, a planarization layer covering the display area and extending into the non-display area and being separated from the dam, and an organic light emitting element having a cathode and disposed on the planarization layer. The cathode extends into the non-display area and exposes a top surface of the planarization layer in the non-display area.

### CROSS-REFERENCE TO RELATED APPLICATIONS

This application claims priority to Korean Patent Application No. 10-2023-0138606 filed on Oct. 17, 2023, in the Korean Intellectual Property Office, the entire contents of which is hereby expressly incorporated by reference into the present application.

### BACKGROUND

### Field

The present disclosure relates to a display device with improved configurations.

### Discussion of the Related Art

In the information era, a field of a display device which visually expresses electrical information signals is being rapidly developed and studies continue to improve the performances of various display devices by providing enhanced properties, such as a thin-thickness, a light weight, and a low power consumption.

A representative display device can include a liquid crystal display device (LCD), a field emission display device (FED), an electro-wetting display device (EWD), an organic light emitting display device (OLED), and the like.

An electroluminescent display device such as an organic light emitting display device is a self-emitting display device that does not require a separate light source such as a backlight unit, which is different from a liquid crystal display device. Therefore, the electroluminescent display device can be manufactured to have a light weight and a small thickness.

Further, since the electroluminescent display device is advantageous not only in terms of power consumption due to the low voltage driving, but also in terms of color implementation, a response speed, a viewing angle, a contrast ratio (CR), it is expected to be utilized in various fields.

In the electroluminescent display device, a plurality of light emitting diodes are used, which include a plurality of organic layers each including an emission layer between two electrodes of an anode electrode and a cathode electrode. In this case, a dam can be provided in a bezel area to provide suppression of moisture permeation into a display area of the display device. However, the formation of the dam can introduce other issues such as cracks in an insulation layer.

Further, in the electroluminescent display device, a plurality of organic and inorganic films including the organic layer and the cathode are deposited above a base substrate. The organic and inorganic films each can have a tolerance for each deposition area/level. However, if the tolerance is exceeded, various defects can be caused in the display device.

### SUMMARY OF THE DISCLOSURE

An object to be achieved by aspects of the present disclosure is to provide a display device which suppresses, minimizes, or prevents a crack of an insulating layer associated with a spacer of a dam and a planarization layer of the display device.

Another object to be achieved by aspects of the present disclosure is to provide a display device which suppresses or minimizes a dark spot which may be formed at an outer periphery of a display area due to a crack of the insulating layer, or to provide a display device which prevents a formation of such dark spot.

Another object to be achieved by aspects of the present disclosure is to provide an improved display device, which addresses the limitations and disadvantages associated with the related art.

Objects of the present disclosure are not limited to the above-mentioned objects, and other objects, which are not mentioned above, can be clearly understood by those skilled in the art from the following descriptions.

In order to achieve the objects as described above, according to an aspect of the present disclosure, a display device can include a substrate (e.g., base substrate) including non-display areas at a first side in which a first pad unit is disposed, a third side in which a second pad unit is disposed, and a second side opposite to the first side, an encapsulation substrate disposed over the substrate and exposing the first pad unit, an adhesive film disposed between the substrate and the encapsulation substrate, a dam disposed between the substrate and the encapsulation substrate at an outer periphery of the adhesive film, a planarization layer which is disposed to cover the second pad unit and is spaced apart from the dam with a first distance at the first side and the third side, an organic layer disposed over the planarization layer to cover a side surface of the planarization layer at the second side, and a passivation layer disposed over the planarization layer and the organic layer and extending into the non-display area to overlap the dam.

Other detailed matters of the example embodiments of the present disclosure are included in the detailed description and the drawings.

According to aspects of the present disclosure, superimposition between the dam and the planarization layer is suppressed, prevented, or minimized, so that a crack of the insulating layer and inflow of outgas of an uncured filler can be suppressed, prevented or minimized. Therefore, formation of a dark spot group which may be generated at an outer periphery of a display area of the display device can be suppressed, prevented, or minimized.

The effects according to aspects of the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an example embodiment of the present disclosure;

FIG. 2 is a cross-sectional view of a sub pixel of the display device of FIG. 1 according to an example of the present disclosure;

FIG. 3 is a view illustrating a part of a cross-section taken along line A-A′ of the display device of FIG. 1 according to an example of the present disclosure;

FIG. 4 is a view illustrating a part of a cross-section taken along line B-B′ of the display device of FIG. 1 according to an example of the present disclosure;

FIG. 5 is a view illustrating a part of a cross-section taken along line C-C′ of the display device of FIG. 1 according to an example of the present disclosure;

FIG. 6 is a plan view of a display device according to another example embodiment of the present disclosure;

FIG. 7 is a view illustrating a cross-section taken along line D-D′ of the display device of FIG. 6 according to an example of the present disclosure;

FIG. 8 is a view illustrating a cross-section taken along line E-E′ of the display device of FIG. 6 according to an example of the present disclosure;

FIG. 9 is a view illustrating a cross-section taken along line F-F′ of the display device of FIG. 6 according to an example of the present disclosure; and

FIG. 10 is a cross-sectional view of a display device according to still another example embodiment of the present disclosure.

### DETAILED DESCRIPTION OF THE EMBODIMENTS

Advantages and characteristics of the present disclosure and methods of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure.

Further, in the following description of the present disclosure, a detailed explanation of known related technologies can be omitted to avoid unnecessarily obscuring the subject matter of the present disclosure. The terms such as “comprising,” “including,” “having,” “consist of,” etc. used herein are generally intended to allow other components to be added unless the terms are used with the term “only”. Any references to singular can include plural unless expressly stated otherwise.

Further, the term “can” fully encompasses all the meanings and coverages of the term “may.”

Components are interpreted to include an ordinary error range even if not expressly stated.

When the position relation between two parts is described using the terms such as “on”, “over,” “above”, “below”, “under”, “below,” “next”, etc., one or more parts can be positioned between the two parts unless the terms are used with the term “immediately” or “directly”.

When an element or layer is disposed “on,” “over,” or “above” another element or layer, another layer or other layers or elements can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. For instance, any feature discussed herein in connection with any embodiment or example may be applied to any display device discussed herein in connection with any other embodiment or example.

Hereinafter, various example embodiments of the present disclosure will be described in detail with reference to the drawings. All the components of each display device according to all embodiments of the present disclosure are operatively coupled and configured.

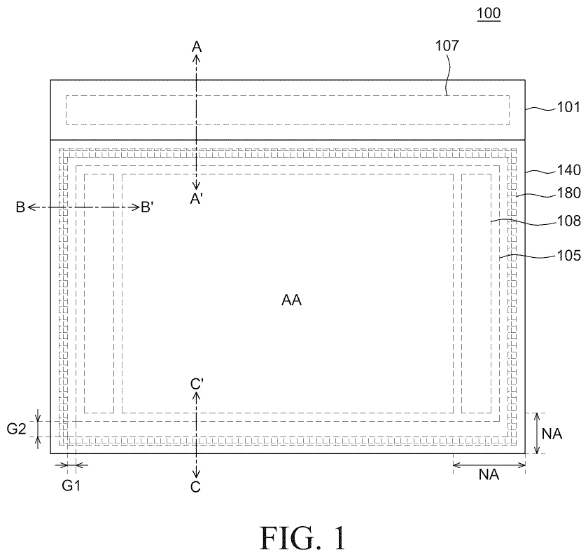

FIG. 1 is a plan view of a display device according to an example embodiment of the present disclosure.

Referring to FIG. 1, a display device 100 according to the example embodiment of the present disclosure can include a substrate 101, an encapsulation substrate 140, pad units 107 and 108, and a dam 180. The substrate 101 and the encapsulation substrate 140 can be referred to as a first substrate and a second substrate, respectively, or can be referred to as a base substrate and an encapsulation substrate, respectively.

The display device 100 is a device for displaying images to a user.

In the display device 100, a display element which displays images, a driving element which drives the display element, and wiring lines which transmit various signals to the display element and the driving element can be disposed. The display element can be defined in different ways depending on a type of the display device 100. For example, when the display device 100 is an organic light emitting display device, the display element can be an organic light emitting element (e.g., organic light emitting diode) which includes an anode, an organic emission layer, and a cathode. For example, when the display device 100 is a liquid crystal display device, the display element can be a liquid crystal display element.

Hereinafter, it is assumed that the display device 100 or any other display device discussed below is an organic light emitting display device including organic light emitting elements, but the display device 100 or the like is not limited to the organic light emitting display device and can be of a different type such as a liquid crystal display device, a micro LED display device, etc.

The display device 100 can be a transparent display device, e.g., transparent and/or flexible organic light emitting display device. However, the present disclosure is not limited thereto.

The display device 100 can include a display area AA (or active area) and a non-display area NA (or non-active area).

The display area AA is an area in which images are displayed in the display device 100.

In the display area AA, a plurality of sub pixels forming a plurality of pixels and one more circuits for driving the plurality of sub pixels can be disposed. The plurality of sub pixels are minimum units which configure the display area AA, where a display element can be disposed in each of the plurality of sub pixels. The plurality (or group) of sub pixels can configure a pixel.

In an example, an organic light emitting diode which includes an anode, an organic light emitting layer, and a cathode can be disposed in each of the plurality of sub pixels, but it is not limited thereto. In the present disclosure, the organic light emitting diode can be any other type of organic light emitting element, which can collectively be referred to as an organic light-light emitting element. Further, circuit(s) for driving the plurality of sub pixels can include one or more driving elements, wiring/conductive lines, and the like. For example, the circuit for driving the sub-pixels can be configured by a thin film transistor, a storage capacitor, a gate line, a data line, and the like, but is not limited thereto.

The non-display area NA is an area where no image is displayed. The non-display area NA can enclose or surround the display area AA entirely or only in parts. The display area AA and the non-display area NA can be in quadrangular shapes. However, the shapes and placements of the display area AA and the non-display area NA are not limited to the example illustrated in FIG. 1.

In other words, the shape and/or arrangement of the display area AA and the non-display area NA can be varied to have shapes and/or arrangements suitable for a design of an electronic device including the display device 100. For example, an example shape of the display area AA can be a pentagon, a hexagon, a circle, an oval, or the like.

In the non-display area NA, various wiring lines and circuits for driving the organic light emitting elements of the display area AA can be disposed. For example, in the non-display area NA, a link line which transmits signals to the plurality of sub pixels and circuits of the display area AA or a driving integrated circuit (IC) such as a gate driver IC or a data driver IC or pad units 107 and 108 can be disposed, but the present disclosure is not limited thereto.

The gate driver IC (or gate driver) can generate and provide gate signals to the pixels of the display device 100, and the data driver IC (or data driver) can generate and provide data signals to the pixels of the display device 100.

The display device 100 can include various additional elements to generate various signals or drive the pixels in the display area AA. The additional elements for driving the pixels can include an inverter circuit, a multiplexer, an electrostatic discharge circuit (ESD), or the like.

For example, the display device 100 can include a timing controller, a power supply, etc. in addition to the gate driver and the data driver for driving the display device 100. The timing controller can receive image signals and control signals from an external host system or the like. The image signals can include a plurality of grayscale data. The control signals can include, for example, a vertical synchronization signal, a horizontal synchronization signal, a data enable signal, and the like.

The display device 100 can further include one or more additional elements associated with one or more functions other than a function of driving a pixel. For example, the display device 100 can include additional elements which provide a touch sensing function, a user authentication function (for example, fingerprint recognition), a multilevel pressure sensing function, or a tactile feedback function. The above-mentioned additional elements can be located in the non-display area NA, and/or the display area AA, and/or an external circuit which is connected to the connecting interface.

The display device according to aspects of the present disclosure can be included in or applied to other electronic devices such as a TV, a mobile terminal such as a smart phone, a navigation system, a computer, a gaming system, an extended reality (XR) system, etc.

The pad units 107 and 108 can be disposed and can be applied with signals from the outside.

The pad units 107 and 108 are disposed in the non-display area NA of the display device 100 to be electrically connected to various wiring lines and the circuit(s) disposed in the display area AA and the printed circuit board(s).

For example, the pad units 107 and 108 serve to transmit signals to the gate lines and the data lines and include a gate pad unit 108 which transmits gate signals to the gate lines and a data pad unit 107 which transmits data signals to the data lines, but are not limited thereto. The area where the data pad unit 107 is disposed can be part of the non-display area NA, but may not be.

The data pad unit 107 can be disposed at one side of the display device 100, for example, can be disposed in the non-display area NA at a first side of the display device 100, but is not limited thereto. For example, the first side here can represent an upper/top side of the display device 100. As a variation, the first side here can be a lower/bottom side of the display device 100.

The gate pad unit 108 can be disposed at one or more sides of the display device 100. For example, the gate pad unit 108 can be disposed in the non-display area NA at a third side of the display device 100, but is not limited thereto. For example, the third side can represent a side portion of the display device 100 adjacent to the upper side and the lower side, such as a left side or a right side of the display device 100 in FIG. 1. However, the present disclosure is not limited thereto. In an example, the gate pad unit 108 can be disposed in either the left or right side of the display device 100, or the gate pad unit 108 can be disposed in each of both the left and right sides of the display device 100.

For example, the data pad unit 107 is electrically connected to the data driver to supply the data voltages to the plurality of data lines. The data driver receives image data from the timing controller to supply the data voltages to the plurality of data lines to drive the plurality of data lines. The data driver can be implemented by including one or more source driver integrated circuits. The data driver can be disposed to overlap with or be adjacent to the data pad unit 107. For instance, the data driver can be disposed be directly on or below the data pad unit 107. In a variation, the data pad unit 107 can include the data driver therein. Similarly, the gate driver can be disposed to overlap with or be adjacent to the gate pad unit 108 (e.g., directly on or below the gate pad unit 108), or the gate pad unit 108 can include the data driver therein.

For example, each source driver integrated circuit can include a shift register, a latch circuit, a digital to analog converter (DAC), an output buffer, or the like. In some cases, the data driver can further include one or more analog to digital converters (ADC) if necessary.

In the meantime, the gate driver outputs the scan signals (gate signals) to the plurality of gate lines to drive the plurality of gate lines. For example, the gate driver sequentially supplies the scan signal to the plurality of gate lines to sequentially drive the plurality of gate lines. The gate driver can sequentially supply a scan signal of an on voltage or an off voltage to the plurality of gate lines according to the control of the timing controller.

The gate driver can be configured by a plurality of gate driving circuits. Here, the plurality of gate driving circuits can correspond to the plurality of gate lines.

For example, each gate driving circuit can include a shift register, a level shifter, and the like.

Each gate driving circuit can be implemented as a gate in panel (GIP) to be embedded in the display device 100. For example, each gate driving circuit can be directly disposed in the gate pad unit 108. The gate driving circuit(s) can be disposed on one or more gate pad units 108 disposed on one side or two opposite sides of the display device 100.

In the meantime, the display device 100 according to one example embodiment of the present disclosure can include a dam 180 in the non-display area NA to ensure that the substrate 101 and the encapsulation substrate 104 are joined/bonded properly and to ensure device reliability such as suppression or prevention of moisture permeation into the display area AA. The dam 180 can include one or more spacers (e.g., see spacers 181 in the other figures) having certain shapes/sizes. For example, the dam 180 can have therein spacers of the same size and/or shape along the non-display area NA, or can have spacers of similar or different sizes and/or shapes along the non-display area NA.

The dam 180 can be disposed so as to enclose the display area AA.

For example, the dam 180 can be disposed as a quadrangular frame shape which encloses entirely the display area AA and has a predetermined curvature in four corners.

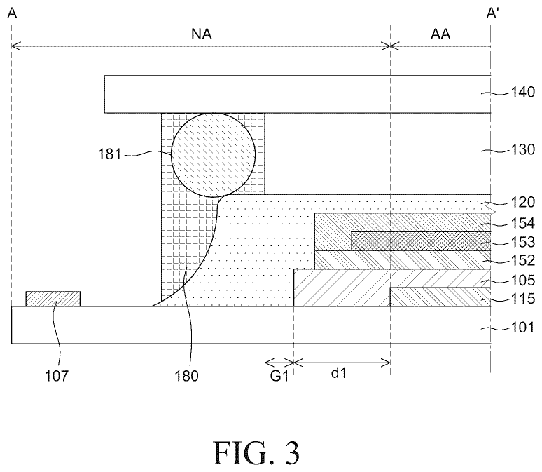

Further, in the display device 100 according to the example embodiment of the present disclosure, a planarization layer 105 is disposed to be spaced apart from the dam 180 with predetermined intervals G1 and G2 to suppress or avoid any superimposition (e.g., overlapping) between the dam 180 and the planarization layer 105. For instance, the planarization layer 105 is spaced apart from the dam 180 by the intervals G1, G2 in the non-display area NA, so that the dam 180 does not contact and does not overlap with (no superimposition) the planarization layer 105. The intervals G1 and G2 can be the same or can be different, e.g., G2>G1, and can be referred to herein a first distance and a second distance, respectively. As a result, a crack of the insulating layer and the inflow of the outgas of the uncured filler can be suppressed or prevented, which will be described below with reference to FIGS. 3 to 10 according to various aspects of the present disclosure.

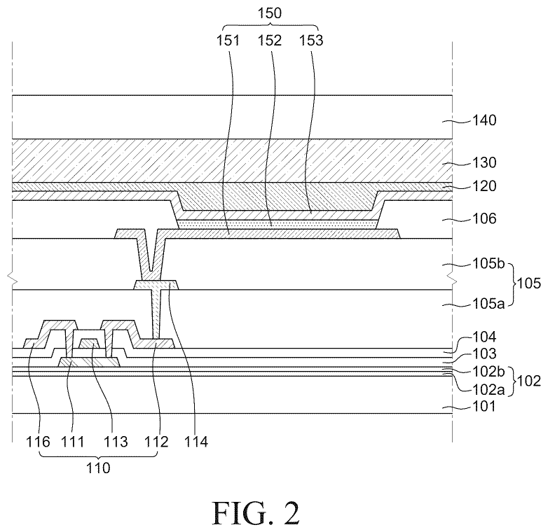

FIG. 2 is a cross-sectional view of a sub pixel of the display device of FIG. 1 according to an example of the present disclosure.

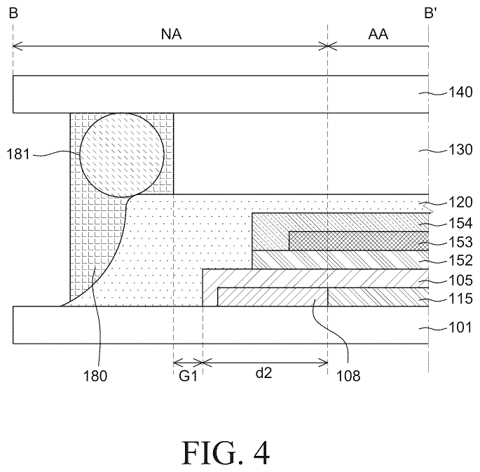

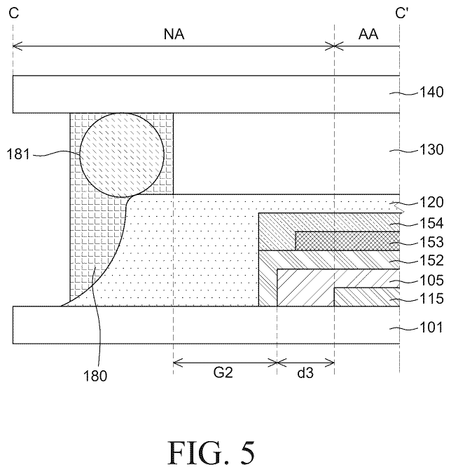

Further, FIG. 3 is a view illustrating a part of a cross-section taken along line A-A′ of the display device of FIG. 1 according to an example of the present disclosure. FIG. 4 is a view illustrating a part of a cross-section taken along line B-B′ of the display device of FIG. 1 according to an example of the present disclosure. FIG. 5 is a view illustrating a part of a cross-section taken along line C-C′ of the display device of FIG. 1 according to an example of the present disclosure.

In FIGS. 3 to 5, for the convenience of description, a pixel unit 115 in the display area AA is schematically illustrated. The pixel unit 115 can include various configurations below the planarization layer 105. Further, in FIGS. 3 and 4, for the convenience of description, the data pad unit 107 and the gate pad unit 108 in the non-display area NA are schematically illustrated. The gate pad unit 108 can include various configurations including the GIP circuit unit.

Particularly, FIG. 3 illustrates a part of the non-display area NA at the first side (first side non-display area NA) and a part of the display area AA of the display device 100 of FIG. 1, and FIG. 4 illustrates a part of the non-display area NA at the left side (left non-display area NA) and a part of the display area AA of the display device 100 of FIG. 1. Further, FIG. 5 illustrates a part of the non-display area NA at the second side (second side non-display area NA) and a part of the display area AA of the display device 100 of FIG. 1.

As mentioned above, the first side refers to an upper or top side of the display device 100 while the second side can refer to a lower or bottom side opposite to the upper side. However, other variations are possible. For instance, the first and second sides can be opposite sides or directly adjacent sides (e.g., sides forming 90 degrees or other degrees).

Hereinafter, an example where a process condition for a normal deposition of the outermost sub pixel of the display device is applied by reflecting a process capability during the deposition of the organic and inorganic films of the display element will be described according to aspects of the present disclosure.

Referring to FIGS. 2 to 5, in the display device (100 in FIG. 1) according to the example embodiment of the present disclosure, a driving element 110 can be disposed on the substrate 101.

Further, the planarization layer 105 can be disposed on the driving element 110.

If the dam 180 is disposed in a quadrangular frame shape which encloses the display area AA, the planarization layer 105 can be disposed in a rectangular shape which encloses the display area AA, including four corners.

Further, an organic light emitting element (e.g., organic light emitting diode) 150 (or the display element) which is electrically connected to the driving element 110 is disposed on the planarization layer 105, and a passivation layer 120 is disposed on the organic light emitting element 150 to suppress or prevent oxygen and moisture from permeating into the organic light emitting element 150.

An adhesive film 130 and the encapsulation substrate 140 can be sequentially disposed on the passivation layer 120. However, the display device 100 according to the example embodiment of the present disclosure is not limited to this laminated structure.

The dam 180 is provided at an outer side of the display device in the non-display area NA between the substrate 101 and an encapsulation substrate 140. The dam 180 can include a plurality of spacers 181 disposed therein, which enhance the reliability of the dam 180. The spacers 181 can have the same size and/or shape along the non-display area NA, or can have different sizes and/or shapes along the non-display area NA.

The substrate 101 can be a glass or plastic substrate. When the substrate 101 is a plastic substrate, polyimide based or polycarbonate based materials are used so that the substrate can have a flexibility. Specifically, polyimide can be applied to a high temperature process and is a coatable material so that polyimide can be frequently used for the plastic substrate. As such, the substrate 101 can be flexible (e.g., bendable, rollable, etc.).

A buffer layer 102 can be disposed on the substrate 101. The buffer layer 102 is a layer which protects various electrodes and wiring lines from impurities such as alkali ions which may be leaked from the substrate 101 or layers therebelow, and has a multilayered structure which is formed by a first buffer layer 102a and a second buffer layer 102b, but is not limited thereto. For example, the buffer layer 102 can have a single-layer structure. Further, the buffer layer 102 can be formed of silicon oxide SiOx, silicon nitride SiNx, or a plurality of layers thereof.

The buffer layer 102 can delay or prevent the diffusion/movement of moisture and/or oxygen which can permeate the substrate 101. Further, the buffer layer 102 can include a multi buffer and/or an active buffer. The active buffer can perform functions of protecting an active layer 111 of the driving element 110 configured by a semiconductor and blocking various types of defects which may be introduced from the substrate 101. The active buffer can be formed of amorphous silicon (a-Si), etc.

As a non-limiting example, the driving element 110 can be formed by sequentially disposing the active layer 111, a gate insulating layer gate electrode 113, an interlayer insulating layer 104, a source electrode 116 and a drain electrode 112. The driving element is electrically connected to the organic light emitting element 150 via the connection electrode 114 to transmit a current or a signal from the driving element 110 to the organic light emitting element 150. For instance, the driving element 110 can be a thin film transistor of various types, and depending on the type of the driving element 110, the locations of the source electrode 116 and the drain electrode 112 can be switched or varied. However, the present disclosure is not limited thereto.

The driving element 110 can be applied in various structures, such as a bottom gate structure in which the gate electrode is located below the active layer and a coplanar structure in which the gate electrode and the source electrode and the drain electrode are disposed on the same planar surface, in addition to the top gate structure.

The active layer 111 can be located on the buffer layer 102. The active layer 111 can be made of poly silicon (p-Si). In this case, a predetermined region can be doped with impurities. Further, the active layer 111 can be made of amorphous silicon (a-Si) or an organic semiconductor material such as pentacene. Moreover, the active layer 111 can be formed of oxide semiconductor.

The gate insulating layer 103 can be located on the active layer 111. For example, the gate insulating layer 103 can be formed of an insulating inorganic material such as silicon oxide SiOx or silicon nitride SiNx or an insulating organic material.

The gate electrode 113 can be located on the gate insulating layer 103. For example, the gate electrode 113 can be formed of various conductive materials, for example, magnesium (Mg), aluminum (Al), nickel (Ni), chrome (Cr), molybdenum (Mo), tungsten (W), gold (Au), or an alloy thereof.

The interlayer insulating layer 104 can be disposed on the gate electrode 113. For example, the interlayer insulating layer 104 can be formed of an insulating material such as silicon oxide SiOx or silicon nitride SiNx or an insulating organic material.

The gate insulating layer 103 and the interlayer insulating layer 104 are selectively removed to form contact holes through which the source and drain regions are exposed, where the source and drain electrodes 116 and 112 can be disposed in such contact holes. The source electrode 116 and the drain electrode 112 can be formed of a material for an electrode, on the interlayer insulating layer 104, as a single layer or a multi-layered structure. If needed, an additional passivation layer which can be configured with an inorganic insulating material can be formed to cover the source electrode 116 and drain electrode 112.

The planarization layer 105 can be disposed on the driving element 110 configured as described above.

The planarization layer 105 can have a multi-layered structure configured by at least two layers. For example, the planarization layer 105 can include a first planarization layer 105a and a second planarization layer 105b, but is not limited thereto.

For example, the first planarization layer 105a can be disposed to cover the driving element 110, but can be disposed to expose a part of the source electrode 116 or the drain electrode 112 of the driving element 110.

The planarization layer 105 can extend into the non-display area NA of the display device 100.

The planarization layer 105 can be an overcoat layer, but is not limited thereto.

In the meantime, according to the example embodiment of the present disclosure, the planarization layer 105 can be spaced apart (separated) from the dam 180 by the predetermined intervals G1 and G2, so that any superimposition (e.g., overlapping) between the dam 180 and the planarization layer 105 can be suppressed and avoided. For example, the planarization layer 105 extends into the non-display area NA and can be disposed to be spaced apart from the dam 180 by the predetermined intervals G1 and G2.

The planarization layer 105 according to the example embodiment of the present disclosure can be spaced apart and separated from the dam 180 with different intervals G1 and G2 according to the position of the display device 100, but the present disclosure is not limited thereto.

For example, the planarization layer 105 is spaced apart from the dam 180 with a first interval (or first distance) G1 (see FIGS. 1, 3, and 4) at the first side and the third side of the display device 100, and is spaced apart from the dam 180 with a second interval (or second distance) G2 (see FIGS. 1 and 5) at the second side of the display device 100. Further, the second interval G2 can be larger than the first interval G1. The second side of the display device 100 is an area in which the pad units 107 and 108 are not disposed. Therefore, various wiring lines or circuits are not disposed so that the margin or extension of the planarization layer 105 which covers and protects the wiring line or the circuit may not be needed at the second side. As a result, the planarization layer 105 at the second side (FIG. 5) may not need to extend into the non-display area NA as much as the part of the planarization layer 105 at the remaining sides (FIGS. 3 and 4) that is extended into the non-display area NA, and thus a sufficient interval (or greater separation distance, G2 in FIG. 5) from the planarization layer 105 to the dam 180 can be secured and provided at the second side. As such, a relationship of G2>G1 (G2 greater than G1) is applied.

Further, at the third side (e.g., left or right side) of the display device 100 (FIG. 4), the dam 180 and the gate pad unit 108 do not overlap with each other. At the third side of the display device 100, the gate pad unit 108 is disposed to be spaced apart (separated) from the dam 180 with a predetermined interval (e.g., interval G1), and the planarization layer 105 can be disposed so as to enclose the gate pad unit 108.

Further, at the third side of the display device 100 (FIG. 4), since the gate pad unit 108 is disposed in the non-display area NA, a distance d2 from an edge of the pixel unit 115 (e.g., at the boundary between the display area AA and the non-display area NA) to an edge of the planarization layer 105 in the non-display area NA of FIG. 4 is larger than a distance d1 from an edge of the pixel unit 115 at the boundary to an edge of the planarization layer 105 at the first side of the display device 100 in FIG. 3, and is also larger than a distance d3 from an edge of the pixel unit 115 at the boundary to an edge of the planarization layer 105 at the second side of the display device 100 in FIG. 5. As such, the relationship of d2>d1 and d2>d3 is applied.

Further, for example, the distance d1 from the edge of the pixel unit 115 to the edge of the planarization layer 105 at the first side of the display device 100 is larger than the distance d3 from the edge of the pixel unit 115 to the edge of the planarization layer 105 at the second side of the display device 100. As such, the relationship of d1>d3 is applied. In that case, the relationship of d2>d1>d3 can be established.

Further, for example, the dam 180 at the first side of the display device 100 (FIG. 3) in which the data pad unit 107 is disposed can partially overlap a power line which is connected to a power signal of the data pad unit 107.

Further, in the display device 100 according to the example embodiment of the present disclosure, the planarization layer 105 is disposed to be spaced apart from the dam 180 with the predetermined intervals G1 and G2 so that any superimposition (overlap) between the dam 180 and the planarization layer 105 can be suppressed or prevented.

Further, at the first side and the third side of the display device 100 (FIGS. 3 and 4), an edge area of the planarization layer 105 is wide to suppress or prevent any short between the cathode 153 and a lower wiring line present therein. However, at the second side of the display device 100 (FIG. 5), there is no lower wiring line present, so that an edge area of the planarization layer 105 can be narrow or narrower than that in FIGS. 3 and 4. For example, a distance between the planarization layer 105 and the cathode 153 (e.g., between the edge of the cathode 153 to the edge of the planarization layer 105 in the non-display area NA in FIG. 5) at the second side can be shorter or less than a distance between the planarization layer 105 and the cathode 153 at the first side and the third side. Further, as described above, for example, the distance d3 from the edge of the pixel unit 115 to the edge of the planarization layer 105 at the second side is shorter than the distances d1 and d2 from the edge of the pixel unit 115 to the edge of the planarization layer 105 at the first side and the third side.

As described above, according to the example embodiment of the present disclosure, the superimposition (overlapping) between the dam 180 and the planarization layer 105 is suppressed or prevented, so that a crack of the insulating layer and the inflow of the outgas of the uncured filler can be suppressed or prevented.

For example, when a substrate and an encapsulation substrate of a display device are bonded, a passivation layer above a planarization layer is pressed by a spacer in a dam, which can cause a crack in the passivation layer. When this crack is generated in the passivation layer, an uncured filler, outgas, or external oxygen flow thereinto can be generated, which can generate a dark spot group or defect.

To address this limitation, according to the example embodiment of the present disclosure, any overlapping between the dam 180 and the planarization layer 105 is entirely avoided by the separation distance/interval G1, G2, so that any crack in the passivation layer 120 and the inflow of the outgas of the uncured filler can be prevented and suppressed. Therefore, a dark spot group or defect does not occur at the outer periphery of the display area AA.

In the meantime, the connection electrode 114 (FIG. 2) which electrically connects the driving element 110 and the organic light emitting element 150 can be disposed on the first planarization layer 105a. Further, various metal layers which serve as electric wires/electrodes such as a data line or a signal line can be disposed on the first planarization layer 105a.

Further, the second planarization layer 105b can be disposed on the first planarization layer 105a and the connection electrode 114. The planarization layer 105 according to the example embodiment of the present disclosure is configured by two layers since various signal lines are increased in accordance with the increased resolution of the display device 100. Therefore, it may become more challenging to dispose all the wiring lines on one layer while ensuring a minimum interval. As a result, an additional planarization layer is provided. The additional planarization layer (for example, the second planarization layer 105b) is added so that there is a margin for disposing wiring lines, which makes it easier to design and dispose the wiring lines/electrodes. Further, when a dielectric material is used for the planarization layer 105 configured by the plurality of layers, the planarization layer 105 can be utilized to form a capacitance between the metal layers.

The second planarization layer 105b can be formed to expose a part of the connection electrode 114, and the drain electrode 112 of the driving element 110 and the anode 151 of the organic light emitting element 150 can be electrically connected via the connection electrode 114.

The organic light emitting element 150 can be configured by sequentially disposing the anode 151, the plurality of organic layers 152, and the cathode 153. For example, the organic light emitting element 150 can be configured by the anode 151 formed on the planarization layer 105, the organic layer 152 formed on the anode 151, and the cathode 153 formed on the organic layer 152.

The display device 100 can be implemented as a top emission type or a bottom emission type. In the case of the top emission type, a reflective layer can be formed below the anode 151 to allow light emitted from the organic layer 152 to be reflected by the anode 151 to be directed upwardly, for example, directed to the cathode 153 thereabove. The reflective layer can be formed of an opaque conductive material having a high reflectance, such as silver (Ag), aluminum (Al), gold (Au), molybdenum (Mo), tungsten (W), chrome (Cr), or an alloy thereof. In contrast, in the case of the bottom emission type, the anode 151 can be only formed of a transparent conductive material, such as indium tin oxide (ITO), indium zinc oxide (IZO), or indium gallium zinc oxide (IGZO). Hereinafter, it is assumed that the display device 100 of the present disclosure is a top emission type. However, the present disclosure is not limited thereto.

The bank 106 (FIG. 2) can be formed in a remaining area excluding the emission area on the planarization layer 105. Therefore, the bank 106 has a bank hole which exposes the anode 151 corresponding to the emission area. The bank 106 can be formed of an inorganic insulating material, such as silicon nitride (SiNx) or silicon oxide (SiOx), or an organic insulating material, such as BCB, an acrylic-based resin or an imide-based resin.

The organic layer 152 can be disposed on the anode 151 exposed by the bank 106. The organic layer 152 can include an emission layer, an electron injection layer, an electron transport layer, a hole transport layer, a hole injection layer, and the like.

The organic layer 152 can extend into the non-display area NA. The organic layer 152 can be disposed on the planarization layer 105 in the non-display area NA.

At this time, for example, an edge of the organic layer 152 is disposed to expose a top edge surface of the planarization layer 105 at the first side and the third side of the display device 100 as shown in FIGS. 3 and 4, whereas the edge of the organic layer 152 as shown in FIG. 5 is disposed to enclose and cover the entire planarization layer 105 at the second side of the display device 100, but is not limited thereto.

Referring to FIGS. 3 and 4, at the first side and the third side of the display device 100 in which the pad units 107 and 108 are disposed, the planarization layer 105 extends into the non-display area NA more than the organic layer 152 so as to cover and protect various wiring lines, circuits, and gate pad unit 108 connected to the data pad unit 107. Therefore, the edge of the organic layer 152 in the non-display area NA can be disposed to end more inside than the edge of the planarization layer 105 in the non-display area NA. For instance, the organic layer 152 is disposed to be spaced apart from the dam 180 by a third distance/interval at the first and third sides of the display device 100, where the third distance is larger than the first distance/interval G1.

In contrast, referring to FIG. 5, at the second side of the display device 100 in which the pad units 107 and 108 are not disposed, the planarization layer 105 does not need to extend into the non-display area NA more than the organic layer 152 extends, so that the organic layer 152 can be disposed to enclose and cover the planarization layer 105 in the non-display area NA. For instance, the top and side surfaces of the planarization layer 105 is entirely covered by the organic layer 152 in the non-display area NA.

In this case, for example, only the passivation layer 120 is disposed between the dam 180 and the planarization layer 105 at the first side and the third side of the display device 100. However, at the second side of the display device 100, the organic layer 152 can be interposed between the dam and the planarization layer 105, in addition to the passivation layer 120.

The cathode 153 can be disposed on the organic layer 152.

In the case of the top emission type, the cathode 153 can include a transparent conductive material. For example, the cathode 153 can be formed of indium tin oxide (ITO), indium zinc oxide (IZO), indium gallium zinc oxide (IGZO), or the like. In the case of the bottom emission type, the cathode 153 can include any one of a group consisting of metal materials such as gold (Au), silver (Ag), aluminum (Al), molybdenum (Mo), magnesium (Mg), palladium (Pd), copper (CU), and an alloy thereof. Alternatively, the cathode 153 can be configured by laminating a layer formed of a transparent conductive material such as indium tin oxide (ITO), indium zinc oxide (IZO), or indium gallium zinc oxide (IGZO) and a layer formed of a metal material such as gold (Au), silver (Ag), aluminum (Al), molybdenum (Mo), magnesium (Mg), palladium (Pd), copper (CU), or an alloy thereof, but is not limited thereto.

The cathode 153 can extend into the non-display area NA. For example, the edge of the cathode 153 can extend less into the non-display area NA than the edge of the organic layer 152 in the non-display area NA. For example, in the non-display area NA, the cathode 153 can be disposed to be inwardly spaced apart from the end of the organic layer 152 with a predetermined distance, but is not limited thereto. In an example, the cathode 153 can be disposed on the organic layer 152 in the non-display area NA and is spaced apart from the dam 180 by a fourth distance which is larger than the third distance mentioned above.

For example, at the third side of the display device 100 (FIG. 4), the planarization layer 105 is disposed so as to enclose and cover entirely the gate pad unit 108 in order to suppress or prevent a short between the circuit unit configured in the gate pad unit 108 therebelow and the cathode 153. At the same time, the cathode 153 can be disposed to be inwardly spaced apart from the end of the organic layer 152 with a predetermined distance.

A capping layer 154 can be disposed on the cathode 153. The capping layer 154 can be formed of a material having a high refractive index and optical absorbance to reduce scattered reflection of external light.

The capping layer 154 can extend into the non-display area NA. For example, the capping layer 154 can be disposed so as to enclose (e.g., cover entirely) the cathode 153 in the non-display area NA. An edge of the capping layer 154 can be disposed to extend further into the non-display area NA than the edge of the cathode 153 in the non-display area NA. The ends of the capping layer 154 and the organic layer 152 can be aligned with each other in the non-display area.

The passivation layer 120 can be disposed on the capping layer 154. The passivation layer 120 can be an inorganic layer and in this case, can be formed of silicon oxide (SiOx), silicon nitride (SiNx), or a plurality of layers thereof. The passivation layer 120 can extend into the non-display area NA. The passivation layer 120 can be disposed to cover the capping layer 154, the cathode 153, the organic layer 152, and the planarization layer 105.

For example, the passivation layer 120 can be disposed to enclose the capping layer 154, the cathode 153, the organic layer 152, and the planarization layer 105 in the non-display area NA.

Further, for example, the passivation layer 120 can be disposed below the dam 180. A portion of the passivation layer 120 directly contacts the substrate 101 in the non-display area NA. For example, the passivation layer 120 can be disposed so as to overlap with the dam 180 between the dam 180 and the substrate 101.

Further, for example, the edge of the passivation layer 120 can be disposed to extend out more than an outer edge of the dam 180, but is not limited thereto. For instance, the edge of the passivation layer 120 can end beyond (or past) the dam 180, end with the dam 180, or end before the dam 180. The edge portion of the passivation layer 120 can have a gradually decreasing shape.

An adhesive film 130 (e.g., bonding film) and the encapsulation substrate 140 can be disposed on the passivation layer 120. The adhesive film 130 can be disposed between the passivation layer 120 and the encapsulation substrate 140.

For example, the adhesive film 130 can be disposed between the passivation layer 120 and the encapsulation substrate 140 inside the dam 180.

The adhesive film 130 can protect the organic light emitting element 150 of the pixel unit 115 from moisture, oxygen, and impacts of the outside together with the passivation layer 120 and the encapsulation substrate 140. The adhesive film 130 can further include an absorbent (also referred to herein as an absorbent material). The absorbent material can be particles having hygroscopicity and absorb moisture and oxygen from the outside to minimize or prevent permeation of the moisture and oxygen into the pixel unit 115, but is not limited thereto.

The adhesive film 130 can include a filler. The filler can be formed using a transparent material so as not to degrade the luminance while the light emitted from the organic light emitting element 150 passes through the encapsulation substrate 140. For example, the filler can be configured by epoxy or olefin or can include talc, calcium oxide (CaO), barium oxide (BaO), zeolite, silicon oxide (SiO), or the like.

The encapsulation substrate 140 can be disposed on the adhesive film 130.

For example, the encapsulation substrate 140 can protect the organic light emitting element 150 of the pixel unit 115 together with the adhesive film 130 and the dam 180. The encapsulation substrate 140 can protect the light emitting element 150 from moisture, oxygen, and impacts of the outside. The encapsulation substrate 140 can be disposed above the substrate 101 so as to expose the data pad unit 107 disposed at one side of the substrate 101 (FIG. 3).

The dam 180 is disposed between the substrate 101 and the encapsulation substrate 140 at the edge of the substrate 101 to reinforce the adhesiveness between the substrate 101 and the encapsulation substrate 140 and block moisture further.

The dam 180 can be disposed in the non-display area NA at the outer periphery of the display area AA. For example, the dam 180 is formed to enclose or surround entirely the pixel unit 115 and the adhesive film 130 when the display device 100 is seen in the planar surface view, and help bonding/joining of the substrate 101 and the encapsulation substrate 140 to be sealed more securely.

As described above, according to the example embodiment of the present disclosure, the planarization layer 105 is spaced apart from the dam 180 with the predetermined intervals G1 and G2 so that any superimposition or overlapping between the dam 180 and the planarization layer 105 is suppressed or prevented.

In this case, a width of the dam 180 can be reduced, while keeping the width of the non-display area NA to be the same as a related art, so that the planarization layer 105 is now spaced apart and separated from the dam 180 by the predetermined intervals G1 and G2, but is not limited thereto. For example, an applied area of the dam 180 is configured at the outer periphery of the planarization layer 105 to suppress and avoid any superimposition/overlapping between the dam 180 and the planarization layer 105.

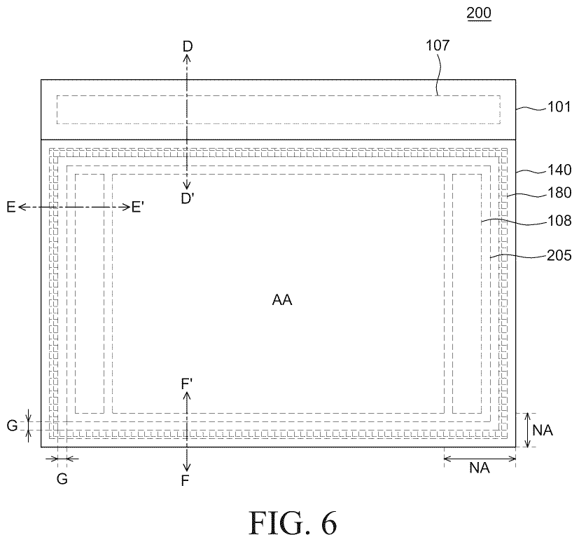

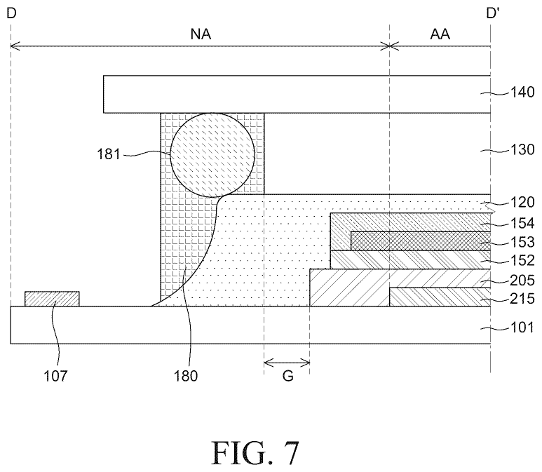

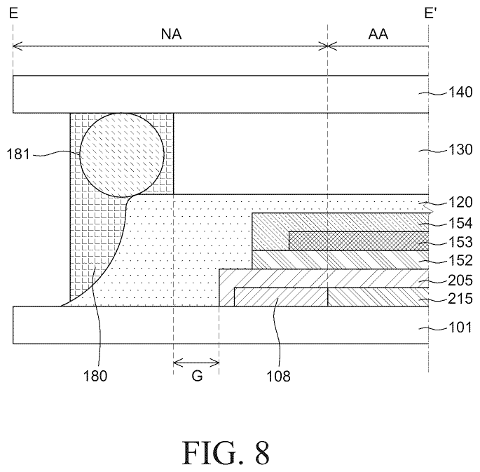

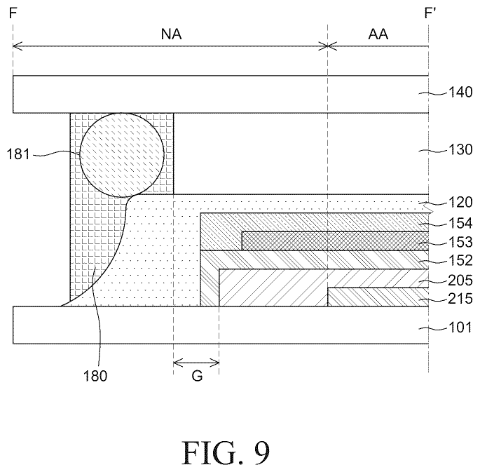

FIG. 6 is a plan view of a display device according to another example embodiment of the present disclosure. FIG. 7 is a view illustrating a cross-section taken along line D-D′ (first side) of the display device of FIG. 6. FIG. 8 is a view illustrating a cross-section taken along line E-E′ (third side) of the display device of FIG. 6. FIG. 9 is a view illustrating a cross-section taken along line F-F′ (second side) of the display device of FIG. 6.

A display device 200 of FIGS. 6 to 9 according to this example embodiment of the present disclosure has the same or substantially same configurations as the display device 100 of FIGS. 1 to 5 except for configurations of a planarization layer 205 and a pixel unit 215. Therefore, a redundant description will be omitted or may be briefly provided. The same configuration will be denoted with the same reference numeral. Here, the description for the same reference numerals can be understood by referring to the description above associated with FIGS. 1 to 5. All the descriptions including all variations pertaining to each element/layer/structure associated with a particular reference numeral in FIGS. 1 to 5 as discussed above are and can be equally applied to the same element/layer/structure associated with the same particular reference numeral in FIGS. 6-9. Thus, such descriptions are not repeated below or may be briefly provided below.

In FIGS. 7 to 9, for the convenience of description, the pixel unit 215 in the display area AA is schematically illustrated. The pixel unit 215 can include various configurations below the planarization layer 205. Further, in FIGS. 7 and 8, for the convenience of description, the data pad unit 107 and the gate pad unit 108 in the non-display area NA are schematically illustrated. The gate pad unit 108 can include various configurations including the GIP circuit unit.

Particularly, FIG. 7 illustrates a part of a non-display area NA at a first side (first side non-display area NA) and a part of a display area AA of the display device 200 of FIG. 6. FIG. 8 illustrates a part of the non-display area NA at a third side (e.g., left/right non-display area NA) and a part of the display area AA of the display device 200 of FIG. 6. Further, FIG. 9 illustrates a part of the non-display area NA at a second side (second side non-display area NA) and a part of the display area AA of the display device 200 of FIG. 6.

Referring to FIGS. 6 to 9, the display device 200 according to this example embodiment of the present disclosure can include a substrate 101, an encapsulation substrate 140, pad units 107 and 108, and a dam 180.

The display device 200 can include the display area AA and the non-display area NA.

The non-display area NA encloses a quadrangular display area AA; however, shapes and placements of the display area AA and the non-display area NA are not limited to the example illustrated in FIG. 6. An example shape of the display area AA can be a pentagon, a hexagon, a circle, an oval, or the like.

The pad units 107 and 108 can be disposed to be applied with a signal from the outside.

For example, the pad units 107 and 108 can include a gate pad unit 108 which transmits a gate signal to a gate line and a data pad unit 107 which transmits a data signal to a data line, but are not limited thereto.

The data pad unit 107 can be disposed at one side of the display device 200, for example, it can be disposed in the non-display area NA at the first side of the display device 200, but is not limited thereto.

The gate pad unit 108 can be disposed at one side of the display device 200, for example, it can be disposed in the non-display area NA at the third side of the display device 200, but is not limited thereto.

For example, the data pad unit 107 is electrically connected to the data driver to supply the data voltage to the plurality of data lines. The data driver can be implemented by including one or more source driver integrated circuits.

In the meantime, for example, the gate driver sequentially supplies the scan signal to the plurality of gate lines to sequentially drive the plurality of gate lines.

The gate driver can be configured by the plurality of gate driving circuits.

Each gate driving circuit is implemented as a gate in panel (GIP) to be embedded in the display device 200. For example, each gate driving circuit can be directly disposed in the gate pad unit 108.

The display device 200 according to this example embodiment of the present disclosure can include the dam 180 in the non-display area NA to ensure device reliability such as suppression or prevention of moisture permeation into the display area AA.

The dam 180 can be disposed so as to enclose the display area AA entirely, but may enclose/surround only in parts. The dam 180 can include a plurality of spacers 181 disposed therein, which enhance the reliability of the dam 180. The spacers 181 can have the same size and/or shape along the non-display area NA, or can have different sizes and/or shapes along the non-display area NA.

In the display device 200 according to this example embodiment of the present disclosure, the planarization layer 205 can be disposed to be spaced apart from the dam 180 with a predetermined interval G. For instance, the separation distance/interval between the dam 180 and the planarization layer 205 in the display device 200 is the same in all sides of the display device 200.

The planarization layer 205 can extend into the non-display area NA.

The planarization layer 205 can be an overcoat layer, but is not limited thereto.

For example, according to this example embodiment of the present disclosure, the planarization layer 205 can extend into the non-display area NA and can be disposed to be spaced apart and separated from the dam 180 by the predetermined interval G.

The planarization layer 205 according to this example embodiment of the present disclosure can be spaced apart from the same interval G (separation distance G) from the dam 180 regardless of the position/side of the display device 200, but the present disclosure is not limited thereto.

For example, the planarization layer 205 can be spaced apart and separated from the dam 180 with the same interval G (or substantially same as the interval G), not only at the first side and the third side of the display device 200 as shown in FIGS. 7 and 8, but also at the second side of the display device 200 as shown in FIG. 9. Here, the substantially same interval G refers to the same interval in consideration of the process error. According to still another example embodiment of the present disclosure, a margin of the planarization layer 205 is not needed for the second side of the display device 200 in which the pad units 107 and 108 are not disposed. Therefore, the pixel unit 215 can expand as much as the reduced interval (G2->G) as compared with the example embodiment of FIG. 5, where the capping layer 154, the cathode 153, the organic layer 152 and the planarization layer 205 are extended further into the non-display area NA but are separated from the dam 180 as shown in FIG. 9. Accordingly, the effect of reducing the bezel area can be achieved.

As described above, in the display device 200 according to this example embodiment of the present disclosure, any superimposition (overlapping) between the dam 180 and the planarization layer 205 is effectively suppressed and prevented, so that any crack in the passivation layer 120 and any inflow of the outgas of the uncured filler can be effectively suppressed and prevented. Therefore, a dark spot group is not generated at the outer periphery of the display area AA.

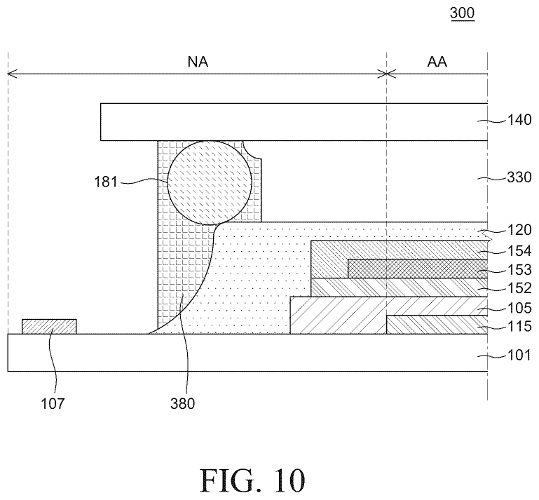

FIG. 10 is a cross-sectional view of a display device according to still another example embodiment of the present disclosure.

A display device 300 of FIG. 10 according to this another example embodiment of the present disclosure has the same or substantially same configurations as the display device 100 of the example embodiment of the present disclosure of FIGS. 1 to 5 except for the configurations of a dam 380 and an adhesive film 330. Therefore, a redundant description will be omitted or may be briefly provided. The same configuration will be denoted with the same reference numeral. Here, the description for the same reference numerals can be understood by referring to the description above associated with FIGS. 1 to 5. All the descriptions including all variations pertaining to each element/layer/structure associated with a particular reference numeral in FIGS. 1 to 5 as discussed above are and can be equally applied to the same element/layer/structure associated with the same particular reference numeral in FIG. 10. Thus, such descriptions are not repeated below or may be briefly provided below.

In FIG. 10, for the convenience of description, the pixel unit 115 in the display area AA is schematically illustrated. The pixel unit 115 can include various configurations below the planarization layer 105. In FIG. 10, for the convenience of description, the data pad unit 107 in the non-display area NA is schematically illustrated.

Particularly, FIG. 10 illustrates a part of the first side non-display area NA and the display area AA of the display device as an example. The first side shown in FIG. 10 is similar to the first side shown in FIG. 3, except for the differences discussed below.

Referring to FIG. 10, the display device 300 according to this example embodiment of the present disclosure can include a substrate 101, an encapsulation substrate 140, a pad unit 107 (108 in FIG. 1), and a dam 380.

The display device according to this example embodiment of the present disclosure can include the dam 380 in the non-display area NA to ensure device reliability such as suppression and prevention of moisture permeation into the display area AA.

The dam 380 can be disposed so as to enclose the display area AA. The dam 380 can include a plurality of spacers 181 disposed therein, which enhance the reliability of the dam 380. The spacers 181 can have the same size and/or shape along the non-display area NA, or can have different sizes and/or shapes along the non-display area NA.

In the display device according to this example embodiment of the present disclosure, the planarization layer 105 can be disposed to be spaced apart and separated from the dam 380 with a predetermined interval (separation distance).

The planarization layer 105 of the display device 300 according to one example of the present disclosure can be spaced apart from the dam 380 with different intervals (separation distances) according to the position/side of the display device. However, the present disclosure is not limited thereto. The planarization layer 105 of the display device 300 according to another example of the present disclosure can be spaced apart from the dam 380 with the same interval for all sides of the display device 300, regardless of the position/side of the display device 300.

According to the example embodiment of the present disclosure, any superimposition between the dam 380 and the planarization layer 105 in the display device 300 is suppressed and prevented, so that any crack in the passivation layer 120 and any inflow of the outgas of the uncured filler can be suppressed and prevented. Therefore, a dark spot group is not generated at the outer periphery of the display area AA in the display device 300.

In the meantime, an adhesive film 330 (bonding layer) and an encapsulation substrate 140 can be disposed on the passivation layer 120.

The adhesive film 330 can be disposed between the passivation layer 120 and the encapsulation substrate 140.

For example, the adhesive film 330 can be disposed between the passivation layer 120 and the encapsulation substrate 140 inside the dam 380.

In the display device 300, the adhesive film 330 can permeate into an upper end of the dam 380 during a vacuum bonding or the like.

For example, the adhesive film 330 can be cured after curing the dam 380.

In one example embodiment of the present disclosure described above, a boundary between the dam 180 and the adhesive film 130 is substantially vertical, e.g., see FIGS. 1-9. However, in still another example embodiment of the present disclosure, the boundary between the dam 380 and the adhesive film 330 may not be vertical during the vacuum bonding due to a viscosity difference of the dam 380 and the adhesive film 330. As such, as illustrated in FIG. 10, the adhesive film 330 can penetrate into the upper end (e.g., upper-inner top area) of the dam 380 and in this case, the boundary between the dam 380 and the adhesive film 330 at the upper end of the dam 380 can be shaped concavely toward the dam 380. This is another example of the boundary area between the dam (e.g., 380) and the adhesive film (e.g., 330) adjacent to the dam in the display device of the present disclosure. Such shaping of the dam can be provided at one or more of all sides of the display device.

As such, all the advantages associated with having the separation distance between the dam and the adhesive film along with other features as mentioned above in connection with FIGS. 1-9 are equally applied and present in the display device of FIG. 10.

One or more aspects of the present disclosure based on the various examples described above can be provided as follows:

According to an aspect of the present disclosure, there is provided a display device. The display device includes a substrate including non-display areas at a first side in which a first pad unit is disposed, a third side in which a second pad unit is disposed, and a second side opposite to the first side, an encapsulation substrate disposed over the substrate and exposing the first pad unit, an adhesive film disposed between the substrate and the encapsulation substrate, dam disposed between the substrate and the encapsulation substrate at an outer periphery of the adhesive film, a planarization layer which is disposed to cover the second pad unit and is spaced apart from the dam with a first distance at the first side and the third side, an organic layer disposed over the planarization layer to cover a side surface of the planarization layer at the second side and a passivation layer disposed over the planarization layer and the organic layer and extending into the non-display area to overlap the dam.

The planarization layer can be disposed to be spaced apart from the dam with the first distance at the second side.

The planarization layer can be disposed to be spaced apart from the dam with a second distance which is larger than the first distance at the second side.

The passivation layer can extend below the dam between the dam and the substrate.

An edge of the passivation layer can be disposed outside more than an outer edge of the dam.

The organic layer can be disposed to be spaced apart from the dam with a third distance which is larger than the first distance at the first side and the third side.

The display device can further comprise a cathode disposed over the organic layer, the cathode can be disposed to be spaced apart from the dam with a fourth distance which is larger than the third distance.

The display device can further comprise a capping layer disposed over the cathode, the capping layer can be disposed to cover a side surface of the cathode.

A part of an interface between the dam and the adhesive film can be not vertical.

A boundary between the dam and the adhesive film can be recessed into the dam, at the upper end of the dam.

The display device can further comprise a spacer disposed in the dam, the spacer does not overlap the planarization layer.

A distance between one end of the planarization layer and one end of the cathode at the third side can be shorter than a distance between one end of the planarization layer and one end of the cathode at the first side and the second side.

A distance between one end of the pixel unit and one end of the planarization layer at the third side can be shorter than a distance between one end of the pixel unit and one end of the planarization layer at the first side and the second side.

Although the example embodiments of the present disclosure have been described in detail with reference to the accompanying drawings, the present disclosure is not limited thereto and can be embodied in many different: forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a base substrate including a non-display area disposed at a first side, a second side and a third side of the display device, wherein a first pad unit is disposed at the first side of the display device, a second pad unit is disposed at the third side of the display device, and the second side is opposite to the first side;
an encapsulation substrate disposed on the base substrate and exposing the first pad unit;
an adhesive film disposed between the base substrate and the encapsulation substrate;
a dam disposed between the base substrate and the encapsulation substrate at an outer periphery of the adhesive film;
a planarization layer disposed to cover the second pad unit in the non-display area, and being spaced apart from the dam by a first distance at the first and third sides of the display device;
an organic layer disposed on the planarization layer to cover a side surface of the planarization layer at the second side; and
a passivation layer disposed on the planarization layer and the organic layer and extending into the non-display area to overlap the dam.

2. The display device according to claim 1, wherein the planarization layer is disposed to be spaced apart from the dam by the first distance at the second side of the display device.

3. The display device according to claim 1, wherein the planarization layer is disposed to be spaced apart from the dam by a second distance at the second side of the display device, the second distance being larger than the first distance.

4. The display device according to claim 1, wherein the passivation layer extends below the dam between the dam and the base substrate.

5. The display device according to claim 1, wherein an edge of the passivation layer is disposed to extend further towards an outside than an outer edge of the dam.

6. The display device according to claim 1, wherein the organic layer is disposed to be spaced apart from the dam by a third distance at the first and third sides of the display device, the third distance being larger than the first distance.

7. The display device according to claim 6, further comprising:
a cathode disposed on the organic layer in the non-display area,
wherein the cathode is disposed to be spaced apart from the dam by a fourth distance which is larger than the third distance.

8. The display device according to claim 7, wherein the cathode exposes a top surface of the organic layer in the non-display area.

9. The display device according to claim 7, further comprising:
a capping layer disposed on the cathode in the non-display area,
wherein the capping layer is disposed to cover a side surface of the cathode.

10. The display device according to claim 1, wherein a part of an interface between the dam and the adhesive film is not vertical.

11. The display device according to claim 10, wherein a boundary between the dam and the adhesive film is recessed into the dam, at an upper end area of the dam.

12. The display device according to claim 1, further comprising:
a spacer disposed in the dam,
wherein the spacer does not overlap the planarization layer.

13. The display device according to claim 1, wherein a distance between one end of the planarization layer and a boundary between the non-display area and a display area at the third side of the display device is larger than a distance between one end of the planarization layer and a boundary between the non-display area and the display area at the first side of the display device, or is larger than a distance between one end of the planarization layer and a boundary between the non-display area and the display area at the second side of the display device.

14. The display device according to claim 1, wherein a distance between one end of the planarization layer and a boundary between the non-display area and a display area at the first side of the display device is larger than a distance between one end of the planarization layer and a boundary between the non-display area and the display area at the second side of the display device.

15. A display device comprising:
a base substrate including a display area and a non-display area surrounding the display area, wherein the non-display area is located at a first side, a second side and a third side of the base substrate, the first and second sides being opposite sides;
a data pad unit disposed in the non-display area at the first side of the base substrate;
an encapsulation substrate disposed on the base substrate and covering the display area while exposing the data pad unit;
a dam disposed between the base substrate and the encapsulation substrate in the non-display are, and surrounding the display area;
a planarization layer covering the display area and extending into the non-display area; and
a passivation layer covering the planarization layer and disposed between the dam and the base substrate in the non-display area,
wherein a first separation distance between the planarization layer and the dam in the non-display area at the second side of the substrate is equal to or greater than a second separation distance between the planarization layer and the dam in the non-display area at the first side of the substrate.

16. The display device according to claim 15, further comprising:
a gate pad unit disposed in the non-display area at the third side of the base substrate, the third side being located between the first and second sides of the base substrate,
wherein the first separation distance is equal to or greater than a separation distance between the planarization layer and the dam in the non-display area at the third side of the substrate.

17. The display device according to claim 15, wherein the passivation layer extends beyond the dam in the non-display area.

18. The display device according to claim 15, further comprising:
an organic layer disposed on the planarization layer and covering a side surface of the planarization layer at the second side of the base substrate; and
an adhesive film disposed on the passivation layer and filling an area between the encapsulation substrate, the dam and the passivation layer in the non-display area.

19. The display device according to claim 15, wherein a distance between one end of the planarization layer and a boundary between the non-display area and the display area at the third side of the base substrate is larger than a distance between one end of the planarization layer and a boundary between the non-display area and the display area at the first side of the base substrate, or is larger than a distance between one end of the planarization layer and a boundary between the non-display area and the display area at the second side of the substrate.

20. The display device according to claim 15, wherein a distance between one end of the planarization layer and a boundary between the non-display area and the display area at the first side of the base substrate is larger than a distance between one end of the planarization layer and a boundary between the non-display area and the display area at the second side of the base substrate.

21. A display device comprising:
a base substrate including a display area and a non-display area surrounding the display area;
an encapsulation substrate disposed on the base substrate and covering the display area;
a dam disposed between the base substrate and the encapsulation substrate in the non-display are;
a planarization layer covering the display area and extending into the non-display area, the planarization layer being separated from the dam; and
an organic light emitting element including a cathode, and disposed on the planarization layer,
wherein the cathode extends into the non-display area, and exposes a top surface of the planarization layer in the non-display area.

22. The display device according to claim 21, further comprising:
a passivation layer covering the planarization layer and disposed between the dam and the base substrate in the non-display area.

23. The display device according to claim 22, further comprising:
a capping layer disposed on the cathode and covering an edge area of the cathode in the non-display area.

24. The display device according to claim 23, wherein the capping layer exposes the top surface of the planarization layer in the non-display area.

25. The display device according to claim 21, wherein the organic light emitting element further includes an organic layer disposed on the planarization layer, and
wherein the organic layer exposes the top surface of the planarization layer in the non-display area.

26. The display device according to claim 21, further comprising:
a gate pad unit disposed on the base substrate in the non-display area,
wherein the planarization layer covers top and side surfaces of the gate pad unit in the non-display area.
